(19) United States
(12) Patent Application Publication
(10) Pub. No.: US 2005/0236368 A1
(43) Pub. Date: Oct. 27, 2005

(54) Method for manufacturing semiconductor device

(76) Inventor: Yuji Akao, Nagano (JP)

Correspondence Address: HARNESS, DICKEY & PIERCE, P.L.C., P.O. BOX 828, BLOOMFIELD HILLS, MI, 48303, US

(21) Appl. No.: 11/103,375

(22) Filed: Apr. 11, 2005

(30) Foreign Application Priority Data
Apr. 26, 2004 (JP) 2004-129659

(51) Int. Cl. H01L 21/302; B24B 1/00; B44C 1/22

(52) U.S. Cl. 216/88; 134/1; 438/692

(57) ABSTRACT

A method for manufacturing a semiconductor device comprises the steps of: giving chemical mechanical polishing to a polishee layer, provided on a semiconductor substrate, by contacting a conditioner against the surface of a polishing pad while contacting the semiconductor substrate, having the polishee layer, against the surface of the polishing pad; cleaning the polishing pad, after giving chemical mechanical polishing to the polishee layer, by supplying a cleaning liquid onto the polishing pad while contacting the conditioner against the polishing pad; cleaning the surface of the semiconductor substrate by contacting the semiconductor substrate 1 against the cleaned polishing pad while supplying the cleaning liquid onto the polishing pad; and giving finish-cleaning to the surface of the semiconductor substrate by contacting the semiconductor substrate against the cleaned polishing pad while supplying the cleaning liquid onto the polishing pad.

### RELATED APPLICATIONS

This application claims priority to Japanese Patent Application No. 2004-129659 filed Apr. 26, 2004 which is hereby expressly incorporated by reference herein in its entirety.

### BACKGROUND

1. Technical Field

The present invention relates to a method for manufacturing a semiconductor device comprising a chemical mechanical polishing step. The present invention especially relates to a method for manufacturing a semiconductor device that can reduce the quantity of foreign matter remaining on the surface of the semiconductor substrate after chemical mechanical polishing.

2. Related Art

In a method for manufacturing a semiconductor device, there is a case where a polishee layer (for example, an interlayer isolation film) formed on a silicon substrate is polished by means of chemical mechanical polishing (CMP).

Each of the drawings in FIG. 4 shows a conventional step for polishing a polishee layer by means of chemical mechanical polishing. First, as shown in FIG. 4A, a silicon substrate 100 is pressed, using a carrier 130, against the surface of a foamed polyurethane polishing pad 120 fixed on a platen 110. The pressing pressure applied here is, for example, 3.0 psi. Further, the platen 110 and the polishing pad 120 are rotated on a rotation axis 112, while the carrier 130 is rotated on a rotation axis 138. Then, polishing slurry is supplied, from a polishing slurry supplying nozzle 122, around the center of rotation on the surface of the polishing pad 120. Thus, the polishee layer formed on the silicon substrate 100 is subjected to chemical mechanical polishing.

Here, a conditioner 140 comprising diamond abrasive grains rubs the surface of the polishing pad 120 to remove polishing dust adhered on the surface of the polishing pad 120 and, at the same time, forms very small irregularities on the surface of the polishing pad 120 for efficient polishing. In addition, the conditioner 140 conducts the above processing by moving back and forth, while rotating on its own axis, along the radial direction of the polishing pad 120.

When the polishee layer is polished by approximately a specified thickness, the supply of the polishing slurry is stopped, as shown in FIG. 4B, and the silicon substrate is cleaned to remove the polishing slurry and polishing dust. Specifically, the conditioner 140 is isolated from the polishing pad 120. Then, leaving the platen 110 and the carrier 130 being rotated, deionized water is supplied, from a deionized water supplying nozzle 124, around the center of rotation on the surface of the polishing pad 120. Here, the pressing pressure applied onto the silicon substrate 100 against the polishing pad 120 must be as low as not to polish the polishee layer on the silicon substrate 100 but not to isolate the silicon substrate 100 from the polishing pad 120 (for example, 0.5 psi). A technique similar to the above is described in, for example, Japanese Unexamined Patent Publication No. 7-130690 (FIG. 7 and Paragraphs 10 to 12).

When foreign matter such as polishing slurry, polishing dust, etc. are left on a semiconductor substrate (for example, a silicon substrate) after polishing, a layer (for example, wiring) to be formed on the polishee layer may not be formed as designed. With the miniaturization of the configuration of semiconductor devices in recent years, the quantity of remaining foreign matter also needs to be reduced. In the conventional steps described above, foreign matter cannot be removed sufficiently.

The present invention has been developed with a consideration of the above problem and aims to provide a method for manufacturing a semiconductor device that can reduce the quantity of foreign matter remaining on the surface of the semiconductor substrate after chemical mechanical polishing.

### SUMMARY

In order to solve the above problem, a method for manufacturing a semiconductor device according to the present invention comprises the steps of:
giving chemical mechanical polishing to a polishee layer, which is provided on a semiconductor substrate, by supplying polishing slurry onto the surface of a polishing pad and contacting a conditioner for cleaning the surface of the polishing pad against the surface of the polishing pad while contacting the semiconductor substrate having the polishee layer against the surface of the polishing pad at the first pressing force;
cleaning the polishing pad, after giving chemical mechanical polishing to the polishee layer, by supplying a cleaning liquid onto the polishing pad, with the semiconductor substrate being contacted against the polishing pad at the second pressing force lower than the first pressing force, while contacting the conditioner against the polishing pad;
cleaning the surface of the semiconductor substrate by contacting the semiconductor substrate against the cleaned polishing pad at the third pressing force higher than the second pressing force while supplying the cleaning liquid onto the polishing pad; and
giving finish-cleaning to the surface of the semiconductor substrate by contacting the semiconductor substrate against the cleaned polishing pad at the fourth pressing force lower than the third pressing force while supplying the cleaning liquid onto the polishing pad.

According to the above method for manufacturing a semiconductor device, the polishing pad is cleaned using the conditioner after giving chemical mechanical polishing to the semiconductor substrate and before cleaning the semiconductor substrate using the polishing pad. Therefore, the semiconductor substrate can be cleaned using the cleaned polishing pad, which makes it less possible that foreign matter such as polishing slurry, polishing dust, etc. remains on the cleaned semiconductor substrate. Such an effect becomes more notable as the number of polishing attempts is increased.

Further, the step for cleaning the semiconductor substrate is divided into two steps. In the first step, the semiconductor substrate is pressed against the polishing pad at a certain pressure level. Then in the second step, the semiconductor substrate is pressed at a pressure as low as not to be isolated from the polishing pad. Therefore, almost all foreign matter can be removed from the semiconductor substrate.

In each of the steps for cleaning and finish-cleaning the surface of the semiconductor substrate, it is preferable to isolate the conditioner from the polishing pad. Further, it is preferable to set the third pressing force lower than the first pressing force.

Another method for manufacturing a semiconductor device according to the present invention comprises the steps of:
giving chemical mechanical polishing to a polishee layer, which is provided on a semiconductor substrate, by supplying polishing slurry onto the surface of a polishing pad while contacting a conditioner for cleaning the surface of the polishing pad and the semiconductor substrate having the polishee layer against the surface of the polishing pad;
cleaning the polishing pad, after giving chemical mechanical polishing to the polishee layer, by supplying a cleaning liquid onto the polishing pad while contacting the conditioner against the polishing pad;
cleaning the surface of the semiconductor substrate by supplying the cleaning liquid onto the cleaned polishing pad while contacting the semiconductor substrate; and
giving finish-cleaning to the surface of the semiconductor substrate by contacting the semiconductor substrate against the polishing pad at a pressing force lower than the pressing force applied in the step for cleaning the surface of the semiconductor.

According to the above method for manufacturing a semiconductor device, the semiconductor substrate can be cleaned using the cleaned polishing pad, which makes it less possible that foreign matter such as polishing slurry, polishing dust, etc. remains on the cleaned semiconductor substrate. Such an effect becomes more notable as the number of polishing attempts is increased.

Another method for manufacturing a semiconductor device according to the present invention comprises the steps of:
giving chemical mechanical polishing to a polishee layer, which is provided on a semiconductor substrate, by supplying polishing slurry onto the surface of a polishing pad and contacting a conditioner for cleaning the surface of the polishing pad against the surface of the polishing pad while contacting the semiconductor substrate having the polishee layer against the surface of the polishing pad at the first pressing force;
cleaning the polishing pad, after giving chemical mechanical polishing to the polishee layer, by supplying a cleaning liquid onto the polishing pad, with the semiconductor substrate being contacted against the polishing pad at the second pressing force lower than the first pressing force, while contacting the conditioner against the polishing pad; and
cleaning the surface of the semiconductor substrate by contacting the semiconductor substrate against the cleaned polishing pad at a pressing force approximately equal to the second pressing force while supplying the cleaning liquid onto the polishing pad.

Another method for manufacturing a semiconductor device according to the present invention comprises the steps of:
giving chemical mechanical polishing to a polishee layer, which is provided on a semiconductor substrate, by supplying polishing slurry onto the surface of a polishing pad while contacting a conditioner for cleaning the surface of the polishing pad and the semiconductor substrate having the polishee layer against the surface of the polishing pad;
cleaning the polishing pad, after giving chemical mechanical polishing to the polishee layer, by supplying the cleaning liquid onto the polishing pad while contacting the conditioner against the polishing pad; and
cleaning the surface of the semiconductor substrate by contacting the semiconductor substrate against the cleaned polishing pad while supplying the cleaning liquid onto the polishing pad.

Another method for manufacturing a semiconductor device according to the present invention comprises the steps of polishing, in a phased manner, a polishee layer, which is provided on a semiconductor substrate, using a plurality of chemical mechanical polishing means, wherein each of the plurality of chemical mechanical polishing means has a polishing pad and a conditioner for cleaning the surface of the polishing pad,
each of the steps for polishing a polishee layer using each of the plurality of chemical mechanical polishing means further comprising the steps of:
giving chemical mechanical polishing to the polishee layer, which is provided on the semiconductor substrate, by supplying polishing slurry onto the surface of the polishing pad and contacting the conditioner for cleaning the surface of the polishing pad against the surface of the polishing pad while contacting the semiconductor substrate having the polishee layer against the surface of the polishing pad at the first pressing force;
cleaning the polishing pad, after giving chemical mechanical polishing to the polishee layer, by supplying a cleaning liquid onto the polishing pad, with the semiconductor substrate being contacted against the polishing pad at the second pressing force lower than the first pressing force, while contacting the conditioner against the polishing pad;
cleaning the surface of the semiconductor substrate by contacting the semiconductor substrate against the cleaned polishing pad at the third pressing force higher than the second pressing force while supplying the cleaning liquid onto the polishing pad; and
giving finish-cleaning to the surface of the semiconductor substrate by contacting the semiconductor substrate against the cleaned polishing pad at the fourth pressing force lower than the third pressing force while supplying the cleaning liquid onto the polishing pad.

According to the above method for manufacturing a semiconductor device, the semiconductor substrate can be cleaned using the cleaned polishing pad, which makes it less possible that foreign matter such as polishing slurry, polishing dust, etc. remains on the cleaned semiconductor substrate. Such an effect becomes more notable as the number of polishing attempts is increased.

Further, since the polishee layer is polished, in a phased manner, using a plurality of chemical mechanical polishing means, polishing tendencies of the plurality of chemical mechanical polishing means are averaged. Therefore, the polished surface can be formed with a higher parallelism to the surface of a silicon wafer.

In the above method for manufacturing a semiconductor device, when the polishee layer is an interlayer isolation film, the effect becomes notable.

### BRIEF DESCRIPTION OF THE DRAWINGS

FIG. 1A is a drawing for describing the step using a chemical mechanical polishing device 2 according to the first embodiment of the present invention; FIG. 1B is a drawing for describing the step subsequent to FIG. 1A; FIG. 1C is a drawing for describing the step subsequent to FIG. 1B; and FIG. 1D is a drawing for describing the step subsequent to FIG. 1C.

FIG. 2 is a schematic cross-sectional drawing showing the configuration of a carrier 30 provided on the chemical mechanical polishing device 2.

FIG. 3 is a schematic drawing of a chemical mechanical polishing device used in a method for manufacturing a semiconductor device according to the second embodiment.

FIG. 4A is a drawing for describing a conventional step for giving chemical mechanical polishing to a polishee layer; and FIG. 4B is a schematic drawing for describing the step subsequent to FIG. 4A.

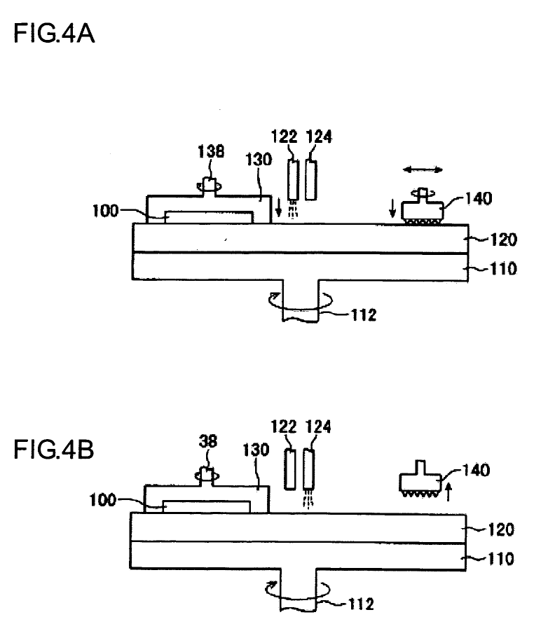

### DETAILED DESCRIPTION

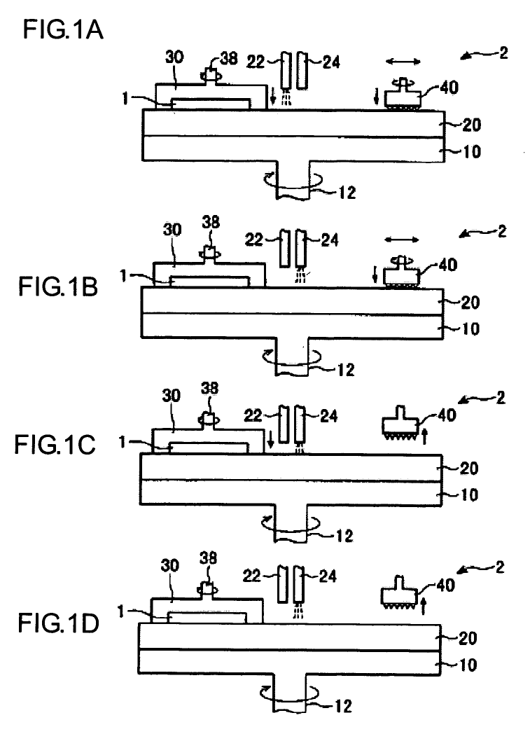

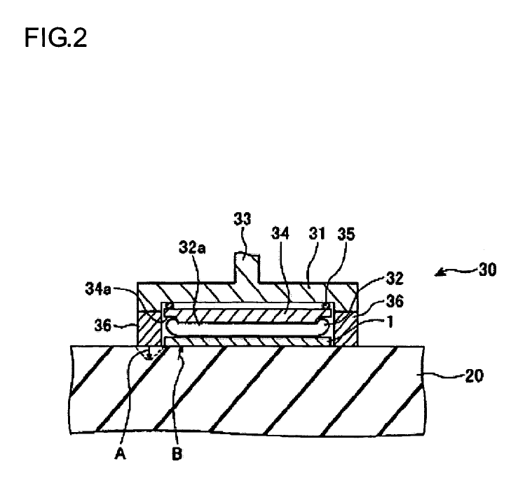

Embodiments of the present invention will now be described with reference to the attached drawings. A method for manufacturing a semiconductor device according to the present invention comprises a step wherein an interlayer isolation film formed on the silicon wafer 1 is polished by a chemical mechanical polishing device 2. FIG. 1 is a drawing for describing the steps conducted by the chemical mechanical polishing device 2. FIG. 2 is a schematic cross-sectional drawing showing the configuration of a carrier 30 for the silicon wafer 1 provided on the chemical mechanical polishing device 2.

First, as shown in FIG. 1A, the silicon wafer 1 is pressed, while being rotated, against a foamed polyurethane polishing pad 20 using the carrier 30. The polishing pad 20, which is fixed on a platen 10, is rotating together with the platen 10 on a rotation axis 12 of the platen 10. Further, polishing slurry is supplied from a polishing slurry supplying nozzle 22, around the center of rotation on the surface of the polishing pad 20. Here, the polishing slurry is supplied at, for example, 200 cc/min. Thus, the interlayer isolation film formed on the silicon wafer 1 is polished.

In addition, during polishing, a conditioner 40 comprising diamond abrasive grains rubs the surface of the polishing pad 20 while rotating on its own axis. Here, the conditioner 40 moves back and forth along the radial direction of the polishing pad, from the rotation center to the edge. Thus, polishing dust is removed from the entire surface of the polishing pad 20. Further, irregularities formed on the entire surface of the polishing pad 20 contribute to efficient polishing. Furthermore, deionized water is not supplied from a deionized water supplying nozzle 24 during polishing. In the present embodiment, the diameter of the polishing pad 20 is 20 inches and the diameter of the conditioner 40 is 4.3 inches.

The configuration of the carrier 30 will now be described with reference to FIG. 2. The carrier 30 comprises a base member 31, which is in an approximate round disk shape. On the bottom surface of a base unit 33, a retainer ring 36, which is vertically movable, is provided concentrically with the base member 31. The retainer ring 36 has an outside diameter of approximately equal to that of the base member 31 and an inside diameter of slightly longer than the diameter of the silicon wafer 1. Inside the retainer ring 36, a membrane retaining member 34 is provided on the bottom surface of the base unit 33 with an inner tube 35 in between. The membrane retaining member 34, which is in an approximate round disk shape, has an outside diameter slightly shorter than the inside diameter of the retainer ring 36. There is a trench on the circumference of the bottom surface of the membrane retaining member 34. The trench 34a is utilized in attaching a membrane 32. A space 32a between the membrane 32 and the membrane retaining member 34 is sealed airtight. The internal pressure of the space 32a is variable. In addition, the internal pressure of the inner tube 35 is also variable.

In order to pick up the silicon wafer 1, the carrier 30 depressurizes the space 32a with the silicon wafer 1 being contacted against the membrane 32. Then, the membrane 32 vacuums the silicon wafer 1, which makes it possible for the carrier 30 to pick up the silicon wafer 1.

In addition, in order to press the silicon wafer 1 against the polishing pad 20, the carrier 30 pressurizes the space 32a. Then, the membrane 32 pushes the silicon wafer 1 downward, that is, against the polishing pad 20.

The pressing force applied by the silicon wafer 1 against the polishing pad 20, which is mainly adjusted in accordance with the internal pressure of the space 32a, can also be adjusted corresponding to the internal pressure of the inner tube 35 or by pressing the retainer ring 36 against the polishing pad 20. In order to increase the pressing force by using the retainer ring 36, the retainer ring 36 needs to be pressed against the polishing pad 20. Then, the polishing pad 20 placed directly under the retainer ring 36 is pushed outward along the circumference, which makes the edge of the silicon wafer 1 pushed upward.

Under the circumstances shown in FIG. 1A, the pressing force applied by the membrane 32 is 3.0 psi, and the pressing force applied by the retainer ring 36 against the polishing pad 20 is 4.9 psi. In addition, the inside of the inner tube 35 is being exhausted.

When polishing is completed, the supply of polishing slurry is stopped, as shown in FIG. 1B, and deionized water, which is used as a cleaning liquid, starts to be supplied, from the deionized water supplying nozzle 24, around the center of rotation on the surface of the polishing pad 20. Here, the platen 10 and the polishing pad 20 are still rotating (at 123 rpm, for example) and the conditioner 40 continues rubbing, while rotating, the surface of the polishing pad 20. The pressing force applied by the conditioner 40 against the polishing pad 20 is, for example, 5 lbf, or 0.2 psi. Further, the silicon wafer 1, which is rotating while being contacted against the polishing pad 20, is pressed at a pressing force as low as not to be isolated from the polishing pad 20. Specifically, for example, the pressing force applied by the membrane 32 is 0.5 psi, the pressing force applied by the retainer ring 36 against the polishing pad 20 is 3.0 psi, and the internal pressure of the inner tube 35 is 6.0 psi.

The processing shown in FIG. 1B is continued for approximately ten seconds, for example. Thus, foreign matter such as polishing slurry, polishing dust, etc. is removed from the surface of the polishing pad 20. Also, foreign matter on the surface of the silicon wafer 1 is removed to some extent.

Next, as shown in FIG. 1C, the conditioner 40 is isolated from the polishing pad 20, while the pressing force applied by the silicon wafer 1 against the polishing pad 20 is increased a little but must be lower than the pressing force applied for polishing. Specifically, the pressing force applied by the membrane 32 is set to 2.0 psi. Other conditions are the same as those for the processing shown in FIG. 1B, including the rotational frequencies of the platen 10, polishing pad 20 and silicon wafer 1.

The processing shown in FIG. 1C is continued for approximately ten seconds, for example. Thus, most of the foreign matter such as polishing slurry, polishing dust, etc. adhered on the surface of the silicon wafer 1 is removed, and the remaining foreign matter becomes easier to be removed. Further, since the polishing pad 20 is already cleaned in the processing shown in FIG. 1B, the surface of the silicon wafer 1 is cleaned efficiently.

Next, as shown in FIG. 1D, the pressing force applied by the silicon wafer 1 against the polishing pad 20 is reduced as low as not to isolate the silicon wafer 1 from the polishing pad 20. Specifically, the pressing force applied by the membrane 32 is set to 3.0 psi. Other conditions are the same as those for the processing shown in FIG. 1C, including the rotational frequencies of the platen 10, polishing pad 20 and silicon wafer 1.

The processing shown in FIG. 1D is continued for approximately ten seconds, for example. Thus, finish-cleaning is given to the surface of the silicon wafer 1, and most of the remaining foreign matter such as polishing slurry, polishing dust, etc. on the surface is removed.

As described above, according to the first embodiment, the polishing pad 20 is cleaned using the conditioner 40 after giving chemical mechanical polishing to the silicon wafer 1 and before cleaning the silicon wafer 1 using the polishing pad 20. Therefore, the silicon wafer 1 can be cleaned using the cleaned polishing pad 20, which makes it less possible that foreign matter such as polishing slurry, polishing dust, etc. remains on the cleaned silicon wafer 1. Such an effect becomes more notable as the number of polishing attempts is increased.

Further, the step for cleaning the silicon wafer 1 is divided into two steps. In the first step, the silicon wafer 1 is pressed against the polishing pad at a certain pressure level. Then in the second step, the silicon wafer 1 is pressed at a pressure as low as not to be isolated from the polishing pad 20. Therefore, almost all foreign matter can be removed from the silicon wafer 1.

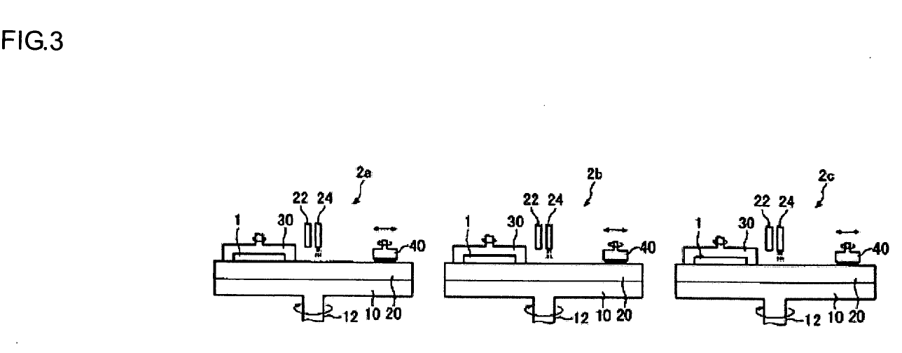

FIG. 3 is a schematic drawing of a chemical mechanical polishing device used in the method for manufacturing a semiconductor device according to the second embodiment. The present embodiment comprises the step of giving chemical mechanical polishing to an interlayer isolation film provided on a silicon wafer 1. The chemical mechanical polishing device shown in FIG. 3 comprises three chemical mechanical polishing means of 2a, 2b and 2c. The configuration and behavior of each chemical mechanical polishing means are almost the same as those of the chemical mechanical polishing device 2 according to the first embodiment. In the present embodiment, the interlayer isolation film on the silicon wafer 1 is polished, in a phased manner, by each of the chemical mechanical polishing means 2a, 2b and 2c. That is, after being polished by the chemical mechanical polishing means 2a to some extent, the interlayer isolation film on the silicon wafer 1 continues to be polished by the chemical mechanical polishing means 2b, and eventually as a finishing step, polished by the chemical mechanical polishing means 2c. Thus, polishing tendencies of the chemical mechanical polishing means 2a, 2b and 2c are averaged, and therefore the polished surface can be formed with a higher parallelism to the surface of the silicon wafer 1.

In the present embodiment, the same effect as obtained in the first embodiment can be obtained.

In addition, the present invention is not limited to the above embodiments and can be varied diversely within the scope of the present invention.

The polishee layer subjected to chemical mechanical polishing is not limited to an interlayer isolation film. For example, the present invention can be applied in forming a tungsten plug for connecting a piece of wiring formed on an interlayer isolation film and another piece of wiring formed under the interlayer isolation film. Such a case comprises the following steps. First, a connection hole is formed on the interlayer isolation film, and then a tungsten film is formed on the interlayer isolation film, when part of the tungsten film is embedded into the connection hole. Next, the tungsten film is removed from the interlayer isolation film by means of chemical mechanical polishing. Thus, a tungsten plug is formed in the connection hole. The present invention is applied to the step for giving chemical mechanical polishing to the tungsten film.

Further, in a trench isolation technique, the polishee layer can be an insulation film (for example, a silicon oxide film) to be removed by polishing when an insulator is embedded into a trench. Such a case comprises the following steps. First, a trench is formed on a semiconductor substrate and then an insulation film is formed on the semiconductor substrate, when part of the insulation film is embedded into the trench. Next, the insulation film is removed from the semiconductor substrate by means of chemical mechanical polishing. Thus, the insulation film is embedded into the trench. The present invention is applied to the step for giving chemical mechanical polishing to the insulation film.

Furthermore, the step shown in FIG. 1C can be omitted in the first embodiment. Here, in the step for cleaning the silicon wafer 1, the pressing force applied by the silicon wafer 1 against the polishing pad 20 can be the same as that in the step for cleaning the polishing pad. In such a case, foreign matter can be removed from the surface of the silicon wafer 1 better than in the conventional technique.

Moreover, in the second embodiment, the number of chemical mechanical polishing means is not limited to three: two or four or more is also acceptable.

1. A method for manufacturing a semiconductor device, comprising the steps of:
giving chemical mechanical polishing to a polishee layer, which is provided on a semiconductor substrate, by supplying polishing slurry onto a surface of a polishing pad and contacting a conditioner for cleaning the surface of the polishing pad against the surface of the polishing pad while contacting the semiconductor substrate having the polishee layer against the surface of the polishing pad at a first pressing force;
cleaning the polishing pad, after giving chemical mechanical polishing to the polishee layer, by supplying a cleaning liquid onto the polishing pad, with the semiconductor substrate being contacted against the polishing pad at a second pressing force lower than the first pressing force, while contacting the conditioner against the polishing pad;
cleaning a surface of the semiconductor substrate by contacting the semiconductor substrate against the cleaned polishing pad at a third pressing force higher than the second pressing force while supplying the cleaning liquid onto the polishing pad; and
giving finish-cleaning to the surface of the semiconductor substrate by contacting the semiconductor substrate against the cleaned polishing pad at a fourth pressing force lower than the third pressing force while supplying the cleaning liquid onto the polishing pad.

2. The method for manufacturing a semiconductor device according to claim 1, wherein the conditioner is isolated from the polishing pad in each of the steps for cleaning and finish-cleaning the surface of the semiconductor substrate.

3. The method for manufacturing a semiconductor device according to claim 1, wherein the third pressing force is lower than the first pressing force.

4. A method for manufacturing a semiconductor device, comprising the steps of:
giving chemical mechanical polishing to a polishee layer, which is provided on a semiconductor substrate, by supplying polishing slurry onto a surface of a polishing pad while contacting a conditioner for cleaning the surface of the polishing pad and the semiconductor substrate having the polishee layer against the surface of the polishing pad;
cleaning the polishing pad, after giving chemical mechanical polishing to the polishee layer, by supplying a cleaning liquid onto the polishing pad while contacting the conditioner against the polishing pad;
cleaning a surface of the semiconductor substrate by supplying the cleaning liquid onto the cleaned polishing pad while contacting the semiconductor substrate; and
giving finish-cleaning to the surface of the semiconductor substrate by contacting the semiconductor substrate against the polishing pad at a pressing force lower than the pressing force applied in the step for cleaning the surface of the semiconductor.

5. A method for manufacturing a semiconductor device, comprising the steps of:
giving chemical mechanical polishing to a polishee layer, which is provided on a semiconductor substrate, by supplying polishing slurry onto a surface of a polishing pad and contacting a conditioner for cleaning the surface of the polishing pad against the surface of the polishing pad while contacting the semiconductor substrate having the polishee layer against the surface of the polishing pad at a first pressing force;
cleaning the polishing pad, after giving chemical mechanical polishing to the polishee layer, by supplying a cleaning liquid onto the polishing pad, with the semiconductor substrate being contacted against the polishing pad at a second pressing force lower than the first pressing force, while contacting the conditioner against the polishing pad; and
cleaning the surface of the semiconductor substrate by contacting the semiconductor substrate against the cleaned polishing pad at a pressing force approximately equal to the second pressing force while supplying the cleaning liquid onto the polishing pad.

6. A method for manufacturing a semiconductor device, comprising the steps of:
giving chemical mechanical polishing to a polishee layer, which is provided on a semiconductor substrate, by supplying polishing slurry onto a surface of a polishing pad while contacting a conditioner for cleaning the surface of the polishing pad and the semiconductor substrate having the polishee layer against the surface of the polishing pad;
cleaning the polishing pad, after giving chemical mechanical polishing to the polishee layer, by supplying the cleaning liquid onto the polishing pad while contacting the conditioner against the polishing pad; and
cleaning a surface of the semiconductor substrate by contacting the semiconductor substrate against the cleaned polishing pad while supplying the cleaning liquid onto the polishing pad.

7. A method for manufacturing a semiconductor device, comprising the steps of polishing, in a phased manner, a polishee layer, which is provided on a semiconductor substrate, using a plurality of chemical mechanical polishing means, wherein each of the plurality of chemical mechanical polishing means has a polishing pad and a conditioner for cleaning a surface of the polishing pad,
each of the steps for polishing a polishee layer using each of the plurality of chemical mechanical polishing means further comprising the steps of:
giving chemical mechanical polishing to the polishee layer, which is provided on the semiconductor substrate, by supplying polishing slurry onto the surface of the polishing pad and contacting the conditioner for cleaning the surface of the polishing pad against the surface of the polishing pad while contacting the semiconductor substrate having the polishee layer against the surface of the polishing pad at a first pressing force;
cleaning the polishing pad, after giving chemical mechanical polishing to the polishee layer, by supplying a cleaning liquid onto the polishing pad, with the semiconductor substrate being contacted against the polishing pad at a second pressing force lower than the first pressing force, while contacting the conditioner against the polishing pad;
cleaning the surface of the semiconductor substrate by contacting the semiconductor substrate against the cleaned polishing pad at a third pressing force higher than the second pressing force while supplying the cleaning liquid onto the polishing pad; and
giving finish-cleaning to the surface of the semiconductor substrate by contacting the semiconductor substrate against the cleaned polishing pad at a fourth pressing force lower than the third pressing force while supplying the cleaning liquid onto the polishing pad.

8. The method for manufacturing a semiconductor device according to claim 1, wherein the polishee layer is an interlayer isolation film.

9. The method for manufacturing a semiconductor device according to claim 4, wherein the polishee layer is an interlayer isolation film.

10. The method for manufacturing a semiconductor device according to claim 5, wherein the polishee layer is an interlayer isolation film.

11. The method for manufacturing a semiconductor device according to claim 6, wherein the polishee layer is an interlayer isolation film.

12. The method for manufacturing a semiconductor device according to claim 7, wherein the polishee layer is an interlayer isolation film.
